(19) United States
(12) Patent Application Publication
(10) Pub. No.: US 2008/0075858 A1
(43) Pub. Date: Mar. 27, 2008

(54) ALD APPARATUS AND METHOD FOR DEPOSITING MULTIPLE LAYERS USING THE SAME

(75) Inventor: Wonyong Koh, Daejeon (KR)

Correspondence Address: KNOBBE MARTENS OLSON & BEAR LLP, 2040 MAIN STREET, FOURTEENTH FLOOR, IRVINE, CA, 92614, US

(73) Assignee: ASM Genitech Korea Ltd., Cheonan-si (KR)

(21) Appl. No.: 11/859,104

(22) Filed: Sep. 21, 2007

(30) Foreign Application Priority Data
Sep. 22, 2006 (KR) 10-2006-0092375

(51) Int. Cl. C23C 16/453; B05C 11/10

(52) U.S. Cl. 427/255.28; 118/702; 118/704

(57) ABSTRACT

ALD apparatuses and methods of depositing multiple layers employ a plurality of reaction spaces. The reaction chamber includes inlets configured to introduce reactant gases sufficient to achieve a first ALD process into a first set of the reaction spaces for a first period of time such that the reactant gases are not mixed one another. The ALD apparatus further includes a driver configured to move the substrates through all of the of reaction spaces in a plurality of cycles during the first period such that a first thin film is deposited by space-divided ALD on each of the substrates. Other inlets introduce reactant gases sufficient to achieve a second ALD process into a second set of the reaction spaces for a second period of time, while purge gas is fed to the first set of reaction spaces. The driver moves the substrates through all of the reaction spaces in a plurality of cycles during the second period such that a second thin film of a different composition from the first film is deposited by space-divided ALD on each of the substrates. Additional sets of reaction spaces can be added for third, fourth, etc. ALD processes. The configuration of the ALD apparatus permits deposition of nanolaminate films on a plurality of substrates for a relatively short period of time while preventing undesired deposition by reaction between the reactant gases.

### CROSS-REFERENCE TO RELATED APPLICATIONS

This application claims priority to and the benefit of Korean Patent Application No. 10-2006-0092375, filed in the Korean Intellectual Property Office on Sep. 22, 2006, the entire contents of which are incorporated herein by reference.

### BACKGROUND

1. Field

The present invention relates to an atomic layer deposition (ALD) apparatus and a method of forming multiple layers using the same.

2. Description of the Related Art

Atomic layer deposition (ALD) is a deposition technique which has been used to deposit materials over features having relatively high aspect ratios. ALD involves the sequential introduction of separate pulses of at least two reactants, resulting in self-limiting adsorption of monolayers of a material on a substrate surface. The reactants are sequentially introduced until a thin film having a desired thickness is formed. For example, a thin film including A and B materials can be formed by repeating a cycle including four steps in sequence: a first reactant gas (A) supply, an inert purge gas supply, a second reactant gas (B) supply, and an inert purge gas supply.

Supplying a pulse of a purge gas between the pulses of the different reactants reduces gas phase reactions between the reactants that might otherwise occur due to excess reactants remaining in the chamber. Accordingly, a thin film having a uniform thickness can be formed on the surface of the substrate regardless of protrusions and depressions on the substrate. The thickness of the thin film may be precisely controlled by controlling the number of cycles of the pulses of the reactant gases in the ALD process. In theoretical ALD, deposition rates depend only upon numbers of cycles and are therefore conformal. In contrast, CVD provides reactants simultaneously and deposition rates depend upon temperature and/or mass flow of the reactants, which are difficult to keep uniform across large substrates.

ALD using reactant gases activated by plasma or another energy source is also known. For example, an aluminum oxide (Al₂O₃) layer may be formed by repeatedly sequentially supplying trimethylaluminum (TMA) and ozone (O₃) gas. An aluminum oxide (Al₂O₃) layer may also be formed by repeatedly sequentially supplying trimethylaluminum (TMA) and oxygen (O₂) gas activated by plasma.

ALD may also be used in forming multiple layers including at least two layers formed of different materials. Each of the at least two layers may be formed by forming several thin layers over one another. Such multiple layers may be used in a semiconductor device or an electro-optic device. For example, triple layers (Al₂O₃/HfO₂/Al₂O₃ or HfO₂/Al₂O₃/HfO₂) formed by forming an aluminum oxide (Al₂O₃) layer and an oxidized hafnium (HfO₂) layer on one another may be used in a charge storage layer of a DRAM or a charge storage layer for a capacitor. Such alternated multilayer structures are sometimes referred to as “nanolaminates.” See, e.g., U.S. Pat. No. 6,902,763, issued Jun. 7, 2005.

Recently, as the density of semiconductor devices increases, extreme ultraviolet (EUW) is expected to be used in a lithography process. Extreme ultraviolet (EUV) is absorbed by almost every material. Thus, lithography equipment using extreme ultraviolet (EUV) may include an extreme ultraviolet mask using a mirror reflecting light, instead of a mask using a lens refracting light. The extreme ultraviolet mask includes a Bragg reflector layer including two thin layers. The two thin layers may have different densities. The Bragg reflector may also include a patterned layer absorbing extreme ultraviolet. The patterned layer is formed on the Bragg reflector layer. FIG. 1 represents one example of the extreme ultraviolet mask.

Referring to FIG. 1, the illustrated extreme ultraviolet mask includes a plurality of thin layers of Si and Mo 104 and 102, which are formed on a substrate 112. The extreme ultraviolet mask may include any other thin layers deposited alternately. The other layers may have different densities such as thin layers of Al₂O₃ and tungsten (W). With respect to a lithography process for formation of a pattern having a thickness of about 40 nm or less, research has been conducted for using extreme ultraviolet (EUV) having a wavelength of about 1 to about 40 nm. When the extreme ultraviolet mask includes a single layer having a thickness of about 6 nm, multiple layers of the extreme ultraviolet mask may have an overall thickness of about 240-360 nm. The Bragg reflector layer may be used in a mirror reflecting X-rays as well as a mirror reflecting extreme ultraviolet.

In the ALD method, it is possible to control a thickness of the resulting thin film. The ALD method can be used to form a Bragg reflector layer having fewer defects because ALD produces less particles compared to a sputtering method or an ion beam deposition method. In the technique of ALD, a thin layer having a thickness of about 0.1 nm or less is formed per every cycle of supplying the reactant gases. About 2400 or more cycles of supplying reactant gases may be repeated until a layer having a desired thickness is deposited. Accordingly, an ALD apparatus capable of processing several substrates simultaneously may be preferable to an ALD apparatus capable of processing a single substrate at a time.

A hot wall or furnace batch type ALD apparatus is one example of an ALD apparatus which is capable of processing several substrates simultaneously. In the furnace batch type ALD apparatus, thin layers are formed on several substrates simultaneously by loading a plurality of substrates into a furnace batch reactor and repeating cycles of supplying reactant gases sequentially to the batch reactor. An example of a furnace batch type ALD apparatus has been disclosed in U.S. Pat. No. 7,022,184, the disclosure of which incorporated by reference. However, the inner volume of the electric furnace batch reactor is relatively large and gas flowing in the electric furnace batch reactor is complex. Thus, it takes very long time to purge the reactant gases of each pulse completely out of the reactor.

Accordingly, if the reactant gases easily react with each other to produce particles and complete purging takes a prohibitively long time, the ALD apparatus having one furnace batch reactor may not be efficient in formation of multiple layers including at least two thin layers.

A spatially divided batch-type ALD apparatus is another example of an ALD apparatus capable of processing several substrates simultaneously. In the spatially divided batch-type ALD apparatus, a processed substrate is transferred sequentially to several processing chambers spatially separated and including different gas atmospheres. Thus, the processed substrate is exposed to reactant gases and a purge gas. Thus, a thin film layer is formed by the surface reaction of the reactant gases on the surface of the substrate. Examples of spatially divided batch-type ALD apparatuses have been disclosed in U.S. Pat. No. 4,058,430, U.S. Pat. No. 5,281274, U.S. Pat. No. 5,730,802, U.S. Pat. No. 6,869,641, U.S. Pat. No. 6,902,620, and U.S. Patent Application Publication No. 2005/0064298.

The ALD apparatuses described above are configured to deposit a single layer including one material by supplying reactant gases and a purge gas. Thus, there is a need to provide an ALD apparatus and a method of supplying reactant gases and a purge gas suitable for depositing multiple layers on a plurality of substrates in a relatively short period of time.

The above information disclosed in this Background section is only for enhancement of understanding of the background of the invention and therefore it may contain information that does not form the prior art that is already known in this country to a person of ordinary skill in the art.

### SUMMARY

The present disclosure has been made in an effort to provide an ALD apparatus and a method of supplying reactant gases used in formation of multiple layers including at least two layers made of different materials and formed by laying several thin layers one upon another.

In one embodiment of the invention, an atomic layer deposition (ALD) apparatus includes a reaction chamber that in turn includes a plurality of reaction spaces. A first set of inlets is configured to introduce a first set of reactant gases for a first ALD process to the reaction spaces such that the first set of reactant gases are not mixed with one another. A second set of inlets is configured to introduce a second set of reactant gases for a second ALD process to the reaction spaces such that the second set of reactant gases are not mixed with one another. A driver is configured to move a plurality of substrates through the reaction spaces. A controller is configured to supply the first set of reactant gases for a first period of time while moving the substrates through the reaction spaces for two or more complete cycles and to supply the second set of reactant gases for a second period of time while moving the substrates through the reaction spaces for two or more complete cycles.

In another embodiment, an atomic layer deposition (ALD) apparatus is configured for depositing multiple layers on multiple substrates. The apparatus includes a first reaction space in selective communication with a first ALD reactant, second reaction space in selective communication with a second ALD reactant, a third reaction space in selective communication with a third ALD reactant, and a fourth reaction space in selective communication with a fourth ALD reactant. The apparatus also includes a driver configured to move a substrates through the first, second, third and fourth reaction chambers. A controller is connected to gas control systems and the driver, with which the controller can conduct a first ALD process on the substrates using the first and third ALD reactants and conduct a second ALD process on the substrates using the second and fourth ALD reactants while the driver moves the substrates through the first, second, third and fourth reaction chambers.

In another embodiment, a method of forming thin films on a plurality of substrates provides a plurality of reaction spaces including a first set of reaction spaces and a second set of reaction spaces. The method includes loading a plurality of substrates into the reaction spaces such that each of the reaction spaces is loaded with at least one of the substrates. A first set of reactant vapors for a first ALD process is supplied into the first set of reaction spaces during a first period of time, where each of the first set of reactant vapors is supplied to a separate one of the first set of reaction spaces. The substrates move through the first set of reaction spaces for two or more complete cycles during the first period of time to thereby deposit a first film on the substrates. A second set of reactant vapors for a second ALD process is deposited into the second set of reaction spaces during a second period of time. Each of the second set of reactant vapors is supplied to a separate one of the second set of reaction spaces. The substrates move through the second set of reaction spaces for two or more complete cycles during the second period of time to thereby deposit a second film on the substrates.

In another embodiment, a method of depositing a plurality of thin films on a substrate is provided. The method includes conducting a first atomic layer deposition (ALD) of a first thin film on the substrate during a first period of time, and conducting a second ALD of a second thin film on the substrate during a second period of time. The first ALD includes (1) supplying at least first and second ALD reactants into first and third reaction spaces, respectively, (2) supplying purge gas into second and fourth reaction spaces, and (3) moving the substrate through the first, second, third and fourth reaction spaces in at least two cycles. The second ALD includes (1) supplying at least third and fourth ALD reactants into the second and fourth reaction spaces, respectively, (2) supplying purge gas into the first and second reaction spaces, and (3) moving the substrate through the first, second, third and fourth reaction spaces in at least two cycles.

An ALD apparatus for depositing multiple layers according to an embodiment includes a reaction chamber including a plurality of reaction spaces and a control system for controlling gas supply to the reaction chamber. Each reaction space is supplied with one of a reactant gas for some time period and an inert gas for another time period, and the apparatus is configured to transfer a plurality of substrates sequentially around the plurality of reaction spaces for the certain time period.

In one example, the reaction chamber includes first to fourth reaction spaces, and the control system may control for a first time period such that the first reaction space is supplied with a first reactant gas, the second reaction space is supplied with an inert gas, the third reaction space is supplied with a second reactant gas, and the fourth reaction space is supplied with the inert gas. Four substrates may be sequentially transferred through the first to fourth reaction spaces repeatedly for multiple cycles during the first time period, thus depositing a first layer.

The control system may control for a second time period such that the first reaction space is supplied with the inert gas, the second reaction space is supplied with a third reactant gas, the third reaction space is supplied with the inert gas, and the fourth reaction space is supplied with a fourth reactant gas, and the four substrates may be sequentially transferred through the first to fourth reaction spaces repeatedly for multiple cycles during the second time period, thus depositing a second layer.

The ALD apparatus may further include a radio frequency (RF) or microwave (MW) energy source for supplying RF or MW power, and the control system may control such that the RF or MW power is supplied synchronously along with at least one of the first time period and the second time period and so that at least one of the first to fourth reactant gases is supplied an activated state, such as by RF or MW with plasma generation.

The control system may control for a third time period such that the first to fourth reaction spaces are all supplied with the inert gas, and the third time period may be a period between the first time period and the second time period. The control system may control for a fourth time period such that the first to fourth reaction spaces are supplied with the inert gas, and the fourth time period may be a period after the second time period and before the subsequent first time period.

In another example, the reaction chamber may include first to sixth reaction spaces, and the control system may control for a first time period such that the first reaction space is supplied with a first reactant gas, the second reaction space and the third reaction space are supplied with an inert gas, the fourth reaction space is supplied with a second reactant gas, and the fifth reaction space and the sixth reaction space are supplied with the inert gas. The plurality of substrates may include first to sixth substrates, and the first to sixth substrates may be sequentially transferred around the first to sixth reaction spaces repeatedly for multiple cycles during the first time period, thus depositing a first layer.

The control system may control for a second time period such that the first reaction space is supplied with the inert gas, the second reaction space is supplied with a third reactant gas, the third reaction space and the fourth reaction space are supplied with the inert gas, the fifth reaction space is supplied with a fourth reactant gas, and the sixth reaction space is supplied with the inert gas, and the first to sixth substrates may be sequentially transferred around the first to sixth reaction spaces repeatedly for multiple cycles during the second time period, thus depositing a second layer.

The control system may control for a third time period such that the first reaction space and the second reaction space are supplied with the inert gas, the third reaction space is supplied with a fifth reactant gas, the fourth reaction space and the fifth reaction space are supplied with the inert gas, and the sixth reaction space is supplied with a sixth reactant gas, and the first to sixth substrates may be sequentially transferred around the first to sixth reaction spaces repeatedly for multiple cycles during the third time period, thus depositing a third layer.

The ALD apparatus may further include a radio frequency (RF) or microwave (MW) energy source for supplying RF or MW power, and the control system may control such that the RF or MW power is supplied synchronously along with at least one of the first time period and the second time period and so that at least one of the first to fourth reactant gases is supplied in an activated state, such as by RF or MW plasma generation. The control system may control for a fourth time period such that the first to sixth reaction spaces are supplied with the inert gas, and the fourth time period may be a period between the first time period and the second time period, between the second and third time periods, or between the third time period and subsequent first time period.

The control system may control for a fifth time period such that the first to sixth reaction spaces are all supplied with the inert gas, and the fifth time period may be a period between the second time period and the third time period. The control system may control for a sixth time period such that the first to sixth reaction spaces are supplied with the inert gas, and the sixth time period may be a period after the third time period and before the first time period.

A method of supplying gases for an ALD apparatus, which includes a reaction chamber including first to fourth reaction spaces and a control system for controlling gas supply to the reaction chamber, according to an exemplary embodiment of the present invention includes supplying, for a first time period, a first reactant gas to the first reaction space, an inert gas to the second reaction space and the fourth reaction space, and a second reactant gas to the third reaction space.

First to fourth substrates may be sequentially transferred around the first to fourth reaction spaces repeatedly during the first time period in a plurality of cycles. The method may further include supplying, for a second time period, an inert gas to the first reaction space and the third reaction space, a third reactant gas to the second reaction space, and a fourth reactant gas to the fourth reaction space. The first to fourth substrates may be sequentially transferred around the first to fourth reaction spaces repeatedly in a plurality of cycles during the second time period.

At least one of the first to fourth reactant gases may be supplied in an activated state, such as by with plasma generation. The method may further include supplying, for a third time period, an inert gas to the first to fourth reaction spaces, and the third time period may be a period between the first and second time periods. The method may further include supplying, for a fourth time period, an inert gas to the first to fourth reaction spaces, and the fourth time period may be a period after the second time period and before the subsequent first time period.

A method of supplying gases for an ALD apparatus, which includes a reaction chamber including first to sixth reaction spaces and a control system for controlling gas supply to the reaction chamber, according to another exemplary embodiment of the present invention includes supplying, for a first time period, a first reactant gas to the first reaction space, an inert gas to the second reaction space and the third reaction space, a second reactant gas to the fourth reaction space, and an inert gas to the fifth reaction space and the sixth reaction space.

First to sixth substrates may be sequentially transferred around the first to sixth reaction spaces repeatedly in a plurality of cycles during the first time period. The method may further include supplying, for a second time period, an inert gas to the first reaction space, the third reaction space, the fourth reaction space, and the sixth reaction space, a third reactant gas to the second reaction space, and a fourth reactant gas to the fifth reaction space.

The first to sixth substrates may be sequentially transferred around the first to sixth reaction spaces repeatedly in a plurality of cycles during the second time period. The method may further include supplying, for a third time period, an inert gas to the first reaction space, the second reaction space, the fourth reaction space, and the fifth reaction space, a fifth reactant gas to the third reaction space, and a sixth reactant gas to the sixth reaction space.

The first to sixth substrates may be sequentially transferred around the first to sixth reaction spaces repeatedly in a plurality of cycles during the third time period. At least one of the first to sixth reactant gases may be supplied in an activated state, such as by plasma generation.

The method may further include supplying, for a fourth time period, an inert gas to the first to sixth reaction spaces, and the fourth time period may be a period between the first time period and the second time period. The method, may further include supplying, for a fifth time period, an inert gas to the first to sixth reaction spaces, and the fifth time period may be a period between the second and third time periods. The method may further include supplying, for a sixth time period, an inert gas to the first to sixth reaction spaces, and the sixth time period may be a period after the third time period and before the first time period.

### BRIEF DESCRIPTION OF THE DRAWINGS

FIG. 1 is a cross-section of one example of a Bragg reflector.

FIG. 2A is a block diagram of an ALD system including an ALD apparatus and a control system according to one embodiment.

FIG. 2B is an exploded perspective view of a reaction chamber of the ALD apparatus of FIG. 2A.

FIG. 3A is a timing diagram of a method of forming multiple thin films in an ALD apparatus according to one embodiment.

FIG. 3B is a timing diagram of a method of forming multiple thin films in an ALD apparatus according to another embodiment.

FIGS. 4A-4C are diagrams illustrating steps of supplying gases into reaction spaces in the method of FIG. 3A.

FIGS. 5A-5C are diagrams illustrating steps of supplying gases into reaction spaces in a method of forming an Al₂O₃ layer and a HfO₂ layer according to another embodiment.

FIG. 6 is a flowchart illustrating a process for forming a triple layer of HfO₂/Al₂O₃/HfO₂ according to another embodiment.

FIGS. 7A-7C are diagrams illustrating steps of supplying gases into reaction spaces in a method of forming an Al₂O₃ layer and a tungsten (W) layer according to another embodiment.

FIG. 8 is a flowchart illustrating a process of forming a Bragg reflector multilayer stack of Al₂O₃/W according to another embodiment.

FIGS. 9A-9D are diagrams illustrating steps of supplying gases into reaction spaces in the method of FIG. 3B.

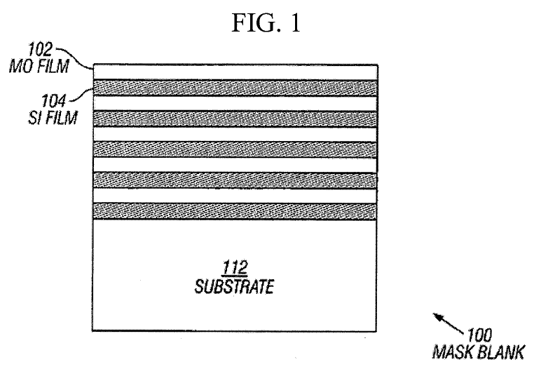

### DETAILED DESCRIPTION OF THE PREFERRED EMBODIMENTS

The instant disclosure will be described more fully hereinafter with reference to the accompanying drawings, in which exemplary embodiments are shown. Those skilled in the art will appreciate that the embodiments may be modified in various ways, all without departing from the spirit or scope of the instant disclosure.

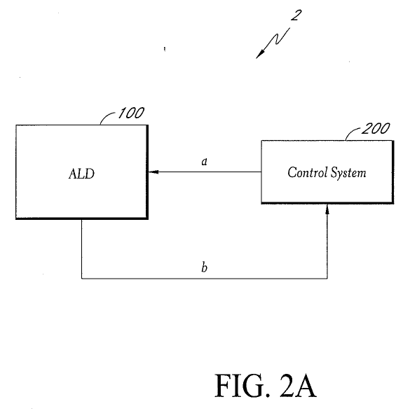

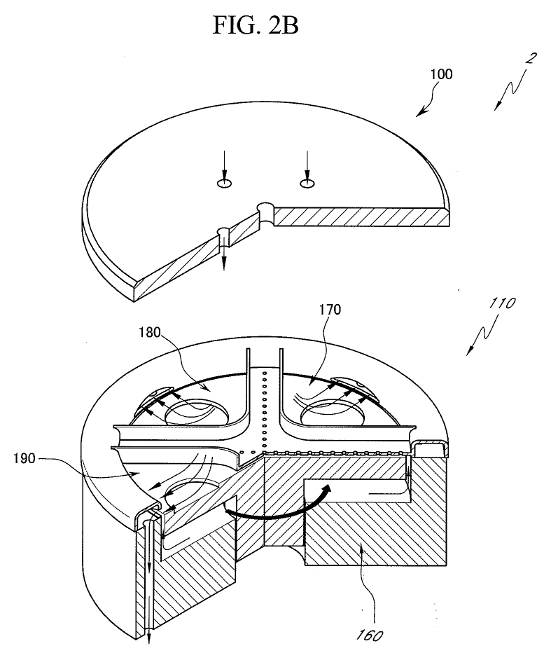

Referring to FIGS. 2A and 2B, an ALD system 2 according to one embodiment will now be described in detail. Referring to FIG. 2A, the ALD system 2 includes an ALD reactor or apparatus 100 and a control system 200. The control system 200 serves to control the operation of the ALD apparatus 100. The control system 200 may include a computer which includes a processor and memory devices, which communicates with valves, temperature controllers and various mechanical moving parts, as will be better understood from the parts and sequences described below.

FIG. 2B illustrates an exemplary reaction chamber 110 of the ALD apparatus 100 of FIG. 2A. The illustrated reaction chamber 110 includes four separate reaction spaces 160, 170, 180, and 190. The reaction space 160 is excised to show a cross-section of the reaction chamber 110. The reaction spaces 160, 170, 180, and 190 are separated from one another. However, the reaction spaces 160, 170, 180, and 190 form a path along which a plurality of substrates can be sequentially transferred. In addition, the ALD apparatus 100 may further include a driver or driving mechanism to transfer the plurality of substrates from one reaction space to another. In the illustrated embodiments, the reaction spaces form a closed path or loop, such that the driver can move the substrates through the reaction spaces in multiple cycles without reversing direction. In other embodiments, the reaction spaces may form an open path, such that the driver can move the substrates through the reaction spaces in multiple cycles by switching directions at each end of the path.

The apparatus comprises a plurality of reaction spaces. The illustrated ALD apparatus 100 has first to fourth reaction spaces 160-190 and can process four substrates simultaneously. Each of the reaction spaces 160-190 may be in selective communication with one ALD reactant. For example, the first to fourth reaction spaces 160-190 may be in selective communication with first to fourth ALD reactants, respectively. However, none of the reaction spaces communicates with multiple mutually reactive ALD reactants. In the illustrated embodiment, the four substrates may be sequentially transferred from one reaction space to another until a thin film having a desired thickness is formed thereon. A skilled artisan will appreciate that the number of reaction spaces can vary widely depending on the design of the ALD apparatus. A skilled artisan will also appreciate that other ALD reactor designs may be suitable for deposition on multiple substrates in a space divisional manner and can also be used for the methods which will be described below. An example of such an ALD reactor is disclosed in U.S. patent application Ser. No. 11/376,817, filed Mar. 15, 2006, the disclosure of which is incorporated herein by reference. As will be clear to the skilled artisan in view of the '817 application, space-divisional or space-divided ALD involves keeping reactants separated in space, and moving the substrate(s) repeatedly into the each reactant space. In the illustrated embodiments of the present disclosure, reactant flow is kept constant rather than pulsed in each active reactant space during a given ALD process.

Each of the reaction spaces may be provided with at least one gas inlet and at least one gas source connected to the gas inlet(s). The gas inlet is configured to introduce a gas supplied from the gas source. In the context of this document, the terms “gas” and “reactant gas” encompass gas and vaporized reactant that is naturally liquid or solid under standard conditions. The illustrated embodiments provide both an ALD reactant vapor and a purge gas to each chamber, and mechanisms to switch flow between reactant and purge. For example, the ALD apparatus 100 may also include gas valves, each of which is used to control gas flow from the gas sources to the gas inlet(s). The gas valves may be electrically controllable. However, gases are not switched during ALD deposition of one material in multiple cycles.

Although not shown, each reaction space of the ALD apparatus 100 may be provided with a separate gas outlet. The gas outlets of the reaction spaces may be sufficiently separated from one another to prevent reactant gases from reacting with one another in the sequences of movement described below. This configuration prevents undesired particles, reactants or by-products from the various reaction spaces from being adsorbed or deposited on the surfaces of the gas outlets and then being exposed to the other reactants from the other reaction spaces.

In other embodiments, the gas outlet of each reaction space may be shared in order to simplify the design of the ALD apparatus. For example, the ALD apparatus of FIG. 2B may include two shared gas outlets. Every two reaction spaces may be connected to a common vacuum pump through one of the two shared gas outlets, instead of the four reaction spaces being connected to a common vacuum pump through one shared gas outlet.

In addition, a portion where the two outlets are connected to each other may be positioned far from each reaction space. This prevents the structures of the outlets from affecting the gas atmosphere in each reaction space, even if the ALD apparatus includes shared gas outlets. The ALD apparatus 100 may also include a gas curtain formed by a flowing inert gas. The gas curtain may be used to prevent gases supplied to the reaction spaces from mixing with one another.

As described above, the control system 200 of FIG. 2A serves to control the operation of the ALD apparatus 100. In the illustrated embodiment, the control system 200 is configured to control the reactant gases supplied to the ALD apparatus 100. The control system 200 may control the types of gases and the durations of gas supplies for each of the reaction spaces 160, 170, 180, and 190.

In one embodiment, the control system 200 may provide commands to the gas valves for controlling gas supplies to the reaction spaces. Each of the valves may be open for a predetermined period of time to supply a selected gas to each of the reaction spaces 160, 170, 180, 190. After such a step of supplying gases is completed, the control system 200 may provide other commands to the valves for supplying gases for the next step. Each substrate may be sequentially transferred from one reaction space to another during each step. The durations of supplying gases may be selected such that a thin film having a predetermined thickness is formed. The process described above may be repeated until thin films having a desired thickness are formed.

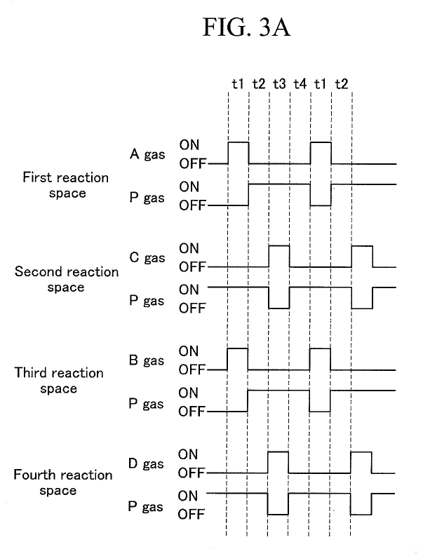

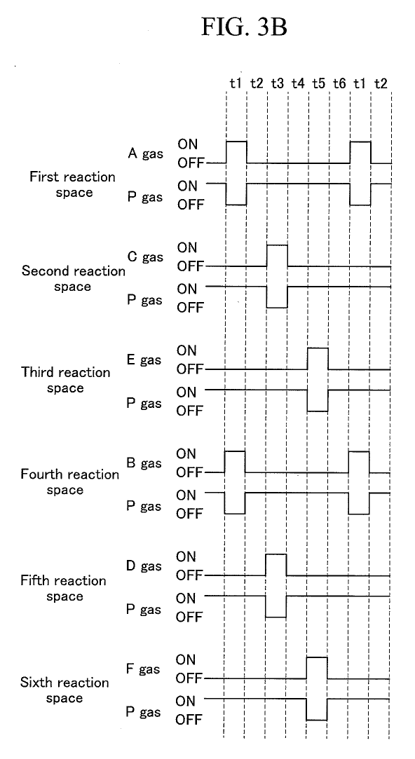

Referring to FIG. 3A and 3B, methods of supplying gases to the reaction spaces of a spatially divided ALD apparatus according to embodiments will now be described. FIG. 3A illustrates one embodiment of a method of forming thin films using an ALD apparatus including four reaction spaces. FIG. 3B illustrates another embodiment of a method of forming thin films using an ALD apparatus including six reaction spaces.

Referring to FIG. 3A, a method of depositing multiple layers according to one embodiment will now be described. In the illustrated embodiment, the multiple layers include two types of thin films: a first thin film and a second thin film. The method can be implemented in an ALD apparatus including first to fourth reaction spaces positioned in order. The first to fourth reaction spaces can form a closed or open path. Each of the reaction spaces is configured to process one substrate at a time. Thus, the four reaction spaces can process four substrates simultaneously. The configuration of the ALD apparatus can be as described above with respect to the reaction apparatus of FIG. 2B. The ALD apparatus may also be provided with a control system to control gas supplies to the reaction spaces, as described above with respect to the control system 200 of FIG. 2A.

In the illustrated embodiment, the ALD apparatus includes (1) a first set of inlets configured to introduce a first set of reactant gases for a first ALD process to the reaction spaces, and (2) a second set of inlets configured to introduce a second set of reactant gases for a second ALD process to the reaction spaces. In the illustrated embodiment, the first ALD process can be conducted for forming a first thin film AB whereas the second ALD process is conducted for forming a second thin film CD of a different composition. The first set of reactant gases can include a first reactant A and a second reactant B. The second set of reactant gases can include a third reactant C and a fourth reactant D.

In the embodiment, two of the four reaction spaces may form a first set of reaction spaces configured to receive the first set of reactant gases. The first set of reaction spaces can include the first and third reaction spaces. The other two of the four reaction spaces may form a second set of reaction spaces configured to receive the second set of reactant gases. The second set of reaction spaces can include the second and fourth reaction spaces. Each of the second set of reaction spaces can be interposed between the two of the first set of reaction spaces.

In the illustrated embodiment, before a first time period t1 starts, four substrates are loaded into the reaction spaces 160, 170, 180, 190. At that time, no reactant gases flow, although purge gases can optionally flow. Then, during the first time period t1, a first reactant gas A, a purge gas P, a second reactant gas B, and a purge gas P are simultaneously supplied into the reaction spaces 160, 170, 180, 190, respectively. The four substrates may be maintained in the reaction spaces 160, 170, 180, 190 for a predetermined period of time which lasts a portion of the first time period t1. In this manner, the first reactant gas A and the second reactant gas B are selectively supplied to the first and third reaction spaces 160, 180 (FIG. 2A), respectively, during the first time period t1.

Then, each of the substrates is transferred to the next reaction space while the first reactant gas A, the purge gas P, the second reactant gas B, and the purge gas P continue to be supplied into the reaction spaces 160, 170, 180, 190, respectively, still during the time period t1. Then, the four substrates are maintained in the reaction spaces 170, 180, 190, 160 adjacent to their original positions for another predetermined period of time which lasts a portion of the first time period t1.

In this manner, the four substrates are sequentially transferred repeatedly through the first to fourth reaction spaces during the first time period t1. Thus, by movement of the substrates from reaction space to reaction space during time period t1, the substrates are sequentially exposed to the first reactant gas A, the purge gas P, the second reactant gas B, and the purge gas P such that a first thin film AB is deposited on the surface of each substrate by ALD. The substrates may continue to be transferred through the reaction spaces, each making a plurality of cycles through the reaction spaces during the first time period t1. The first time period t1 can be selected such that first thin films AB having a desired thickness are deposited on the plurality of substrates during the first time period t1. While in the described sequence of movement the substrates pause in each reaction space, in other embodiments, the substrates may be substantially continuously moved through the reaction spaces 160, 170, 180, 190. Preferably each substrate spends sufficient time in each cycle in each of the first and third reaction spaces to allow ALD reactions to saturate the substrate surfaces.

Then, the control system controls or switches gas supplies for a second time period t2. During the second time period t2, all of the first to fourth reaction spaces are supplied with the purge gas P. The supply of the purge gas P into all the reaction spaces prevents any of the first reactant gas A remaining in the first reaction space and any of the second reactant gas B remaining in the third reaction space from flowing into the second and fourth reaction spaces positioned between the first and third reaction spaces. In one embodiment, the second time period t2 may be shorter than the first time period t1. In other embodiments, the second time period t2 may be omitted, particularly if other mechanisms prevent gas phase interactions between mutually reactive ALD reactants.

Next, as shown in FIG. 3A, the control system controls or switches gas supplies for a third time period t3. During this period, the purge gas P is supplied to the first reaction space. In addition, a third reactant gas C is supplied to the second reaction space while the purge gas P is supplied to the third reaction space. A fourth reactant gas D is supplied to the fourth reaction space. The substrates are sequentially transferred repeatedly in a plurality of cycles through the first to fourth reaction spaces during the third time period t3. Accordingly, each of the substrates is sequentially exposed to the purge gas P, the third reactant gas C, the purge gas P, and the fourth reactant gas D such that a second thin film CD is deposited on the surface of each substrate by ALD. In this manner, the third reactant gas C and the fourth reactant gas D are selectively supplied to the second and fourth reaction spaces 170, 190 (FIG. 2A), respectively, during the third time period t3.

Next, the control system controls or switches gas supplies for a fourth time period t4 such that the first to fourth reaction spaces are supplied with the purge gas P. In one embodiment, the fourth time period t4 may be shorter than the third time period t3. In other embodiments, the fourth time period t4 may be omitted, particularly if other mechanisms prevent gas phase interactions between mutually reactive ALD reactants.

As described above, the first time period t1 to the fourth time period t4 form a super cycle for sequentially forming the first thin film AB and the second thin film CD on a plurality of substrates. Each of these films are formed by multiple ALD cycles generated by moving substrates through separated reaction spaces, whereas each super cycle involves switching gases to conduct different ALD processes (e.g., to form film AB in time period t1 and to form film CD in time period t3). A multiple layer structure including a plurality of first and second thin films stacked upon one another may be formed by repeating the super cycle of the time periods t1 to t4. The control system may be configured to control the number of super cycles as well as the durations (number of ALD cycles) for each of the time periods t1-t4 so as to control the thickness of the multiple layers and the number of the thin films in the multiple layers.

In certain embodiments, the ALD apparatus may further include a gas activating device such as a radio frequency (RF) or microwave (MW) source for supplying RF or MW power. For example, the gas activating device may include an RF electrode, an RF coil, etc. The RF power may be applied during at least one time period, e.g., the first time period t1 and/or the third time period t3 of FIG. 3A such that at least one of the reactant gases A, B, C, and D is supplied in a plasma-activated state. The control system may serve to control activation of the reactant gases. As will be appreciated by the skilled artisan, other mechanisms can be used to activate or excite reactant gases.

In the illustrated embodiment, the reaction spaces are supplied with reactant gases and a purge gas in a manner to prevent different reactant gases from contacting each other while the multiple layers are deposited on the substrates. For example, the first reaction space may be supplied with the first reactant gas A during the first time period t1 while the second reaction space is supplied with the purge gas P. In addition, the first reaction space may be supplied with the purge gas P during the second time period t2 while the second reaction space is supplied with the third reactant gas C. In this manner, the reaction spaces are supplied with gases such that the gases do not react with one another, thereby preventing undesired deposition.

In FIG. 3A, the first to fourth time periods t1-t4 have the same duration. However, the durations of the first to fourth time periods t1, t2, t3, and t4 may be different from one another. For example, the second and fourth time periods t2 and t4, representing pauses between different ALD processes, may be shorter than the first and third time periods t1 and t3, or may be omitted. In addition, the first time period t1 and the third time period t3 may be selected to form first and second thin films having a desired thickness. In reality, for self-limiting ALD processes, “durations” of time periods t1 and t3 are merely proxies for numbers of ALD cycles caused by movement of the substrates, since in ALD only numbers of cycles affect thickness. In the ALD apparatus, the control system may serve to control the thickness of each thin films as well as the number of the thin films.

Referring to FIG. 3B, a method of depositing multiple layers according to another embodiment will be described below. In the illustrated embodiment, the multiple layers include three types of thin films: a first thin film, a second thin film, and a third thin film, each deposited by spatially separated ALD sequences. The method can be implemented in an ALD apparatus including six separate reaction spaces configured to process six substrates simultaneously. The six reaction spaces include a first to sixth reaction spaces positioned in order. The six reaction spaces may form a closed or open path. When described as a modification of FIG. 2B by the addition of fifth and sixth reaction spaces, the six reaction spaces may instead be described as first, second, fifth, third, fourth, sixth reaction spaces positioned in order while forming a closed path. A skilled artisan will appreciate that the numbered labels of the reaction spaces are arbitrary for the purpose of naming different reaction spaces. A skilled artisan will also appreciate that additional reaction spaces can be interposed between two of the six reaction spaces depending on the design of the ALD apparatus. In certain embodiments, the additional reaction spaces can be used for providing a purge gas between any two reaction spaces simultaneously supplying reactant gases for given ALD processes. The ALD apparatus may be provided with a control system for supplying gases for depositing multiple layers by ALD.

In the illustrated embodiment, the ALD apparatus includes (1) a first set of inlets configured to introduce a first set of reactant gases for a first ALD process to the reaction spaces, (2) a second set of inlets configured to introduce a second set of reactant gases for a second ALD process to the reaction spaces; and (3) a third set of inlets configured to introduce a third set of reactant gases for a third ALD process to the reaction spaces. In the illustrated embodiment, the first ALD process can be conducted for forming a first thin film AB whereas the second ALD process is conducted for forming a second thin film CD. The third ALD process may be conducted for forming a third thin film EF. The first set of reactant gases can include a first reactant A and a second reactant B. The second set of reactant gases can include a third reactant C and a fourth reactant D. The second set of reactant gases can include a third reactant C and a fourth reactant D. The third set of reactant gases can include a fifth reactant E and a sixth reactant F.

In the embodiment, two of the six reaction spaces may form a first set of reaction spaces configured to receive the first set of reactant gases. In the example of FIG. 3A, the first set of reaction spaces can include the first and fourth reaction spaces. Another two of the six reaction spaces may form a second set of reaction spaces configured to receive the second set of reactant gases. The second set of reaction spaces can include the second and fifth reaction spaces. Each of the second set of reaction spaces can be interposed between the two of the first set of reaction spaces. Yet another two of the six reaction spaces may form a third set of reaction spaces configured to receive the third set of reactant gases. The third set of reaction spaces can include the third and sixth reaction spaces. Each of the third set of reaction spaces can be interposed between one of the first set of reaction spaces and one of the second set of reaction spaces.

Referring to FIG. 3B, the control system controls gas supplies for a first time period t1. During the first time period t1, a first reactant gas A is supplied to a first reaction space while a second reactant gas B is supplied to a fourth reaction space. In addition, an inert purge gas P is supplied to second, third, fifth, and six reaction spaces. During the first time period t1, the substrates are each sequentially transferred through the first to sixth reaction spaces. Accordingly, the six substrates are each sequentially exposed to the first reactant gas A, the purge gas P, the purge gas P, the second reactant gas B, the purge gas P, and the purge gas P such that a first thin film AB is deposited on the surface of each substrate by ALD. The first time period t1 can be selected to have sufficient ALD cycles (e.g., movement through all six reaction spaces) such that first thin films AB having a desired thickness are deposited on the plurality of substrates during the first time period t1. In this manner, the first reactant gas A and the second reactant gas B are selectively supplied to the first and fourth reaction spaces, respectively, during the first time period t1.

Then, the control system controls or switches gas supplies for a second time period t2. During the second time period t2, the first to sixth reaction spaces may each be supplied with the purge gas P, as shown. All the reaction spaces may be supplied with the purge gas P to prevent the first reactant gas A (remaining in the first reaction space) and the second reactant gas B (remaining in the fourth reaction space) from flowing into the second and third reaction spaces and the fifth and sixth reaction spaces between the first reaction space and the fourth reaction space. The second time period t2 for supplying the purge gas P may be shorter than the first time period t1 for supplying the reactant gases A and B. In other embodiments, the second time period t2 may be omitted, particularly where other mechanisms prevent phase interactions between the mutually reactive ALD reactants.

Next, the control system controls or switches gas supplies for a third time period t3. During the third time period t3, a third reactant gas C is supplied to the second reaction space while a fourth reactant gas D is supplied to the fifth reaction space. During this time period, the purge gas P is supplied to the first, third, fourth, and sixth reaction spaces. In this manner, the third reactant gas C and the fourth reactant gas D are selectively supplied to the second and fifth reaction spaces, respectively, during the third time period t3.

During the third time period t3, the substrates are each sequentially transferred through the first to sixth reaction spaces. Accordingly, the substrates are each sequentially exposed to the purge gas P, the third reactant gas C, the purge gas P, the purge gas P, the fourth reactant gas D, and the purge gas P such that a second thin film CD is deposited on the surface of each substrate by ALD.

Next, the control system controls or switches gas supplies for a fourth time period t4. The first to sixth reaction spaces are supplied with the purge gas P during the fourth time period t4. The fourth time period t4 for supplying the purge gas P may be shorter than the third time period t3 for supplying the reactant gases C and D. In other embodiments, the fourth time period t4 may be omitted, particularly where other mechanisms prevent gas phase interactions between ALD reactants C and D.

Subsequently, the control system controls or switches gas supplies for a fifth time period t5. A fifth reactant gas E is supplied to the third reaction space while a sixth reactant gas F is supplied to the sixth reaction space for the fifth time period t5. The purge gas P is supplied to the first, second, fourth, and fifth reaction spaces during the fifth time period t5. The substrates are sequentially transferred repeatedly through the first to the sixth reaction spaces during the fifth time period t5. Thus, the substrates are sequentially exposed to the purge gas P, the purge gas P, the fifth reactant gas E, the purge gas P, the purge gas P, and the sixth reactant gas F such that a third thin film EF is deposited on the surface of each substrate by ALD. In this manner, the fifth reactant gas E and the sixth reactant gas F are selectively supplied to the third and sixth reaction spaces, respectively, during the fifth time period t3.

Next, the control system controls or switches gas supplies for a sixth time period t6. The first to sixth reaction spaces are supplied with the purge gas P during the sixth time period t6. The sixth time period t6 for supplying the purge gas P may be shorter than the fifth time period t5 for supplying the reactant gases E and F. In other embodiments, the sixth time period t6 may be omitted, particularly where other mechanisms prevent gas phase interactions between the mutually reactive ALD reactants E and F.

During the first to sixth time periods t1-t6, the first to third thin films AB, CD, and EF are formed over one another on the plurality of substrates. By repeating the process described above, additional layers including first to third thin films can be formed on the third thin film EF formed during the sixth time period t6. The method can be repeated until a desired number of layers are formed.

The control system may control the gas supplies such that each reaction space is supplied with one reactant gas or a purge gas in a manner to prevent different reactant gases from contacting each other while the multiple layers are deposited on each substrate.

In certain embodiments, the ALD apparatus may use RF or MW power during at least one time period, e.g., the first, third, and fifth time periods, t1, t3, and t5 shown in FIG. 3B. In such embodiments, at least one of the reactant gases A, B, C, D, E, and F is supplied in a state activated by plasma or other excitation means. The control system may also serve to control activation of the reactant gases.

In FIG. 3B, the first to sixth time periods t1, t2, t3, t4, t5, and t6 have substantially the same duration. In other embodiments, the durations of the first to sixth time periods t1, t2, t3, t4, t5, and t6 may be different from one another. Particularly, the second time period t2, the fourth time period t4, and the sixth time period t6 may be shorter than the other time periods t1, t3, and t5. In other embodiments, the second, fourth, and sixth time periods t2, t4, t6 may be omitted. In addition, the first time period t1, the third time period t3, and the fifth time period t5 may be varied in terms of numbers of cycles each wafer takes in movement through the reaction spaces by the control system 200, depending on the desired thicknesses of the first to third thin films.

Note that the examples of FIGS. 3A and 3B each involve two-reactant ALD processes, but the skilled artisan can readily adapt the sequences to incorporate more complicated (e.g., three-reactant or four-reactant) ALD sequences.

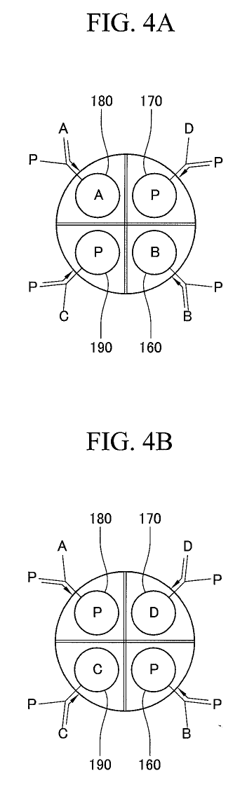

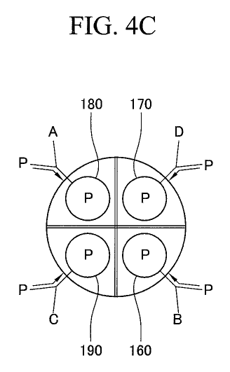

With reference to FIG. 4A to FIG. 9C, methods of depositing multiple layers including a plurality of different thin films according to embodiments will now be described in detail. In the methods, each reaction space is supplied with either a single reactant gas and/or a purge gas to prevent two or more reactants from reacting with one another. The drawings include designations of either purge gases (“P”) or reactants (“A,” “B,” “C,” “D,” “E,” “F,” “Al,” “O,” “Hf,” “WF6,” “SiH₄,”) within reaction spaces at different stages of the sequences.

First, as shown in FIG. 4A, the reaction space 180 is supplied with a first reactant gas A while the reaction space 160 is supplied with a second reactant gas. The reaction space 170 is supplied with an inert gas P. The reaction space 190 is supplied with the inert gas P. The substrates are sequentially transferred repeatedly through the reaction spaces 160 to 190 such that the surface of each of the substrates is sequentially exposed to the second reactant gas B, the inert gas P, the first reactant gas A, and the inert gas P. In this manner, a first thin film AB is deposited on the surface of each of the substrates by ALD. The gas supply scheme shown in FIG. 4A and movement of the substrates may be used for the first time period t1 of FIG. 3A.

Referring to FIG. 4B, the reaction space 160 is supplied with the inert gas P while reaction space 170 is supplied with a fourth reactant gas D. The reaction space 180 is supplied with the inert gas P. The reaction space 190 is supplied with a third reactant gas C. The substrates are sequentially transferred repeatedly through the reaction spaces 160 to 190 so that the surface of each of the substrates is sequentially exposed to the inert gas P, the fourth reactant gas D, the inert gas P, and the third reactant gas C. In this manner, a second thin film CD is deposited on the surface of each of the substrates by ALD. The gas supply scheme shown in FIG. 4B and movement of the substrates may be used for the third time period t3 of FIG. 3B.

Referring to FIG. 4C, all the reaction spaces may be supplied with an inert purge gas. This configuration can prevent the reactant gases A, B, C, and D from flowing into adjacent reaction spaces. The gas supply scheme shown in FIG. 4C may be used for the second and fourth time periods t2, t4 of FIG. 3B, between deposition of the first thin film AB and the second thin film CD. This manner of use involves supplying each reaction space with either a reactant gas or a purge gas while substrates move from chamber to chamber, thereby avoiding interactions in the gas phase between reactants.

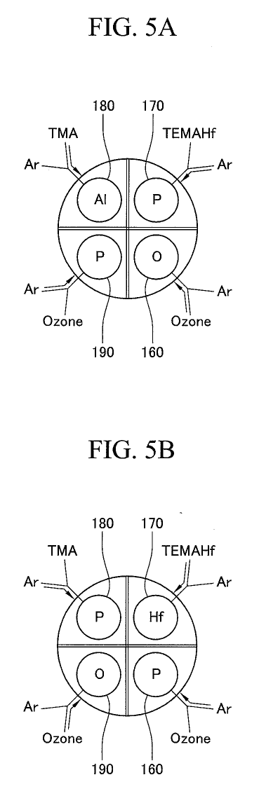

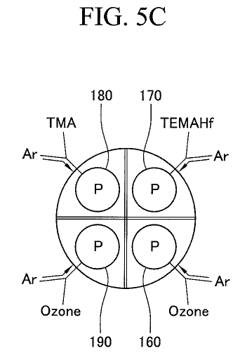

Referring to FIG. 5A to 5C, a method of depositing multiple layers including one or a plurality of Al₂O₃ layers and one or a plurality of HfO₂ layers will now be described. In the method, reaction spaces are supplied with gases or vapors such as trimethylaluminum (Al(CH₃)₃, TMA), tetrakisethylmethylamido hafnium (Hf[N(CH₃)(C₂H₅)]₄, TEMAHf), ozone (O₃), and argon (Ar). In the illustrated embodiment, TMA, ozone, ozone, and TEMAHf can serve to be the first, second, third, and fourth reactant gases, respectively, of FIGS. 4A-4C. In other embodiments, nitrogen (N₂) gas or helium (He) may be used as an inert gas instead of argon (Ar) gas.

Referring to FIG. 5A, for depositing an Al₂O₃ layer on a plurality of substrates, the reaction space 160 is supplied with the ozone (O₃) gas as an O precursor. The reaction space 170 is supplied with the argon (Ar) gas. The reaction space 180 is supplied with the TMA gas as an Al precursor. The reaction space 190 is supplied with the argon (Ar) gas. Rotating or moving substrates through these spaces causes ALD of Al₂O₃.

Referring to FIG. 5B, for depositing an HfO₂ layer on the substrates, the reaction space 160 is supplied with the argon (Ar) gas. The reaction space 170 is supplied with the TEMAHf gas as an Hf precursor. The reaction space 180 is supplied with the Ar gas. The reaction space 190 is supplied with the ozone (O₃) gas as an O precursor. In the illustrated embodiment, the TMA gas or the TEMAHf gas has a lower vapor pressure. Thus, the TMA gas or the TEMAHf gas may be supplied together with a carrier gas. The ozone (O₃) gas may each be supplied with oxygen (O₂) gas. For purging all reaction spaces, the reaction spaces 160, 170, 180, and 190 may be supplied with Ar gas or other inactive purge gas as shown in FIG. 5C. As noted previously, this stage may represent purging between ALD depositions of different films, or during loading/unloading.

Referring to FIGS. 5A-5C and 6, a process of depositing multiple layers on four substrates will now be described in detail. The multiple layers may include a triple-layer of HfO₂/Al₂O₃/HfO₂ on multiple substrates using the apparatus of FIGS. 5A-5C.

Referring to FIG. 6, each reaction space is supplied with an inert gas such as argon (Ar) (S100) as shown in FIG. 5C. Then, four substrates are loaded into the reaction spaces (S110). Next, the reactant gases are supplied as shown in FIG. 5B (S120) while the four substrates are sequentially transferred through the four reaction spaces 160, 170, 180, and 190 repeatedly until a HfO₂ layer having a desired thickness is formed (S130).

Next, all the reaction spaces are supplied with the inert gas such as argon (Ar) as shown in FIG. 5C (S140). Then, the reactant gases are supplied as shown in FIG. 5A (S150) while the four substrates are sequentially transferred through the four reaction spaces 160, 170, 180, and 190 repeatedly until an Al₂O₃ layer having a desired thickness is formed (S160).

Next, all the reaction spaces are supplied with the inert gas such as argon (Ar) as shown in FIG. 5C (S170). Subsequently, the reactant gases are supplied as shown in FIG. 5B (S180) while the four substrates are sequentially transferred through the four reaction spaces 160, 170, 180, and 190 repeatedly until another HfO₂ layer having a desired thickness is formed (S190). Next, all the reaction spaces are supplied with the inert gas such as argon (Ar) as shown in FIG. 5C (S200). After triple-layers of HfO₂/Al₂O₃/HfO₂ having the desired thickness are deposited, the substrates are unloaded from each reaction space (S210).

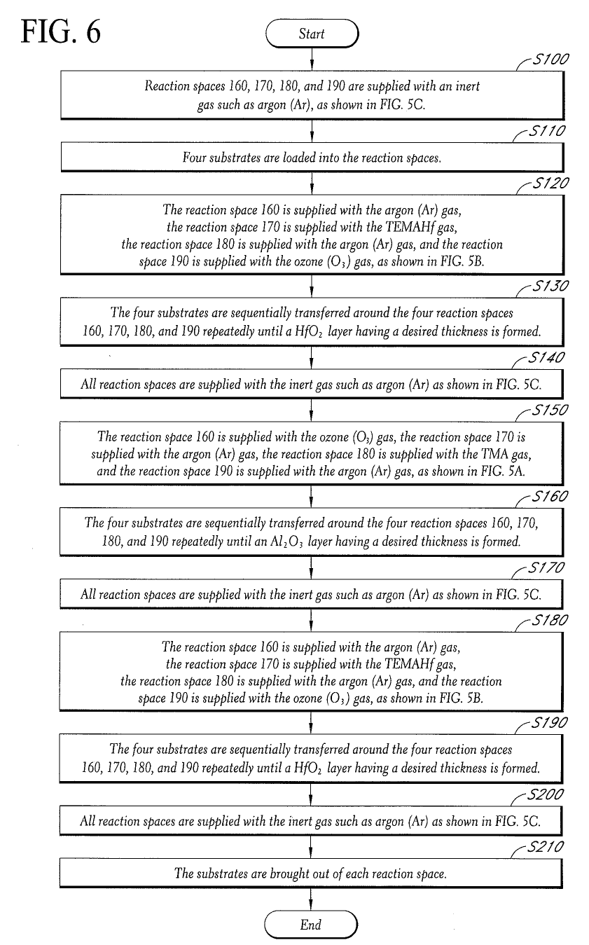

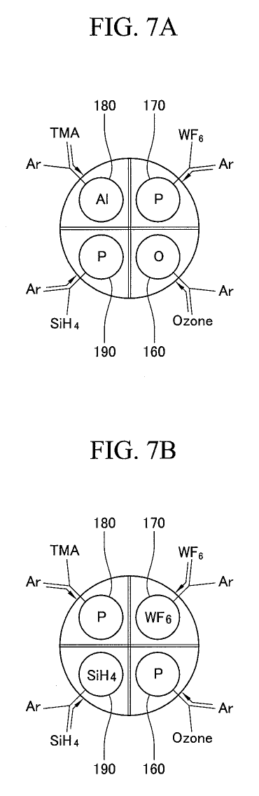

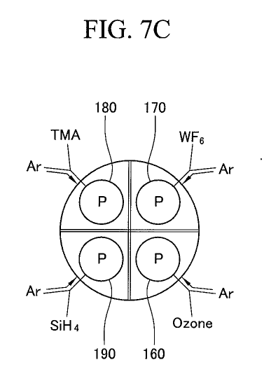

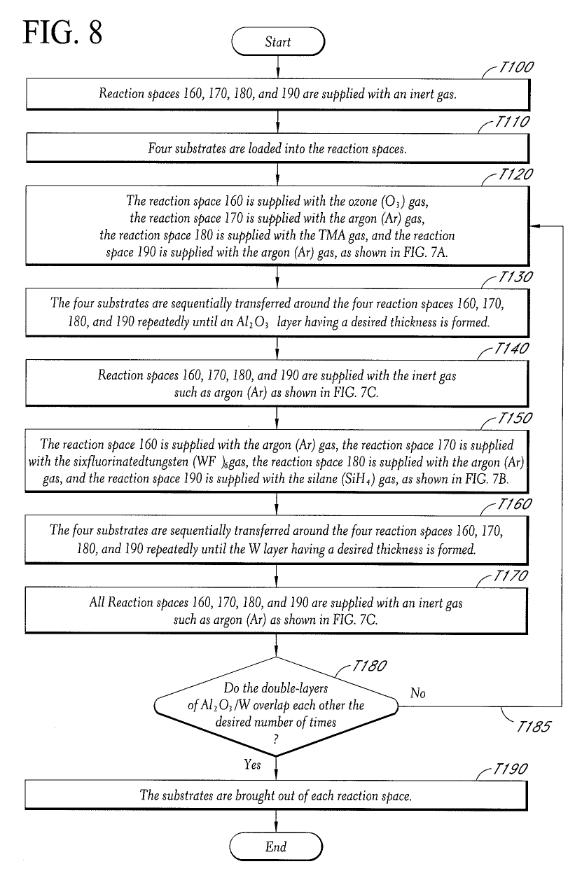

Referring to FIG. 7A to FIG. 7C, a method of forming a Bragg reflector layer including an Al₂O₃ layer and a tungsten (W) layer will now be described in detail. In the method, reaction spaces are supplied with gases such as TMA, ozone (O₃), hexafluorotungsten (WF₆), silane (SiH₄), and argon (Ar). In the illustrated embodiment, TMA, ozone, SiH₄, and WF₆ can serve to be the first, second, third, and fourth reactant gases, respectively, of FIGS. 4A-4C. In other embodiments, nitrogen (N₂) gas or helium (He) may be used as an inert gas instead of the argon (Ar) gas.

Referring to FIG. 7A, for depositing an Al₂O₃ layer on a plurality of substrates, the reaction space 160 is supplied with ozone (O₃) gas. The reaction space 170 is supplied with argon (Ar) purge gas. The reaction space 180 is supplied with TMA gas. The reaction space 190 is supplied with argon (Ar) purge gas. ALD is conducted in this state while substrates are cycled through these reaction spaces.

Referring to FIG. 7B, for depositing a tungsten (W) layer, the reaction space 160 is supplied with argon (Ar) gas. The reaction space 170 is supplied with WF₆ gas. The reaction space 180 is supplied with argon (Ar) gas. The reaction space 190 is supplied with SiH₄ gas, which serves as a reducing agent to strip halides from the adsorbed tungsten complex. In the illustrated embodiment, the WF₆ gas and the SiH₄ gas may each be supplied mixed with an inert gas or hydrogen (H₂) gas. ALD is conducting in this state while substrates are cycled through these reaction spaces. For purging all the reaction spaces, the reaction spaces 160, 170, 180, and 190 are supplied with Ar gas, as shown in FIG. 7C.

Referring to FIGS. 7A-7C and 8, a process of forming a Bragg reflector layer including a plurality of double-layers of Al₂O₃/W on four substrates using the ALD apparatus of FIGS. 7A-7C will be described in detail. Referring to FIG. 8, each reaction space is supplied with an inert gas such as argon (Ar) (T100) as shown in FIG. 7C. Then, four substrates are loaded into the reaction spaces (T110).

The reactant gases are supplied as shown in FIG. 7A while the four substrates are sequentially transferred through the four reaction spaces 160, 170, 180, and 190 repeatedly until an Al₂O₃ layer having a desired thickness is formed (T130). Then, for purging all the reaction spaces, the reaction spaces 160, 170, 180, and 190 are supplied with Ar gas (T140), as shown in FIG. 7C. Next, the reactant gases are supplied (T150), as shown in FIG. 7B while the four substrates are sequentially transferred through the four reaction spaces 160, 170, 180, and 190 repeatedly until the W layer having a desired thickness is formed (T160).

It is determined whether sufficient deposition has occurred (T180). The cycle of supplying gases is repeated (T185) until a desired number of the double-layers of Al₂O₃/W are formed on the substrates. After the multiple layers including a plurality of double-layers of Al₂O₃/W and having a desired thickness are deposited, the substrates are unloaded from each reaction space (T190).

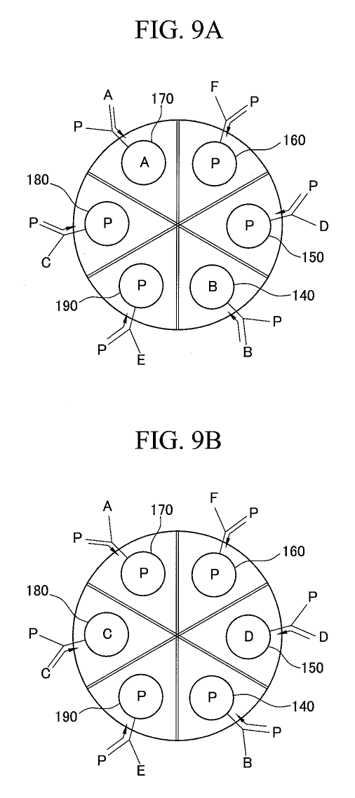

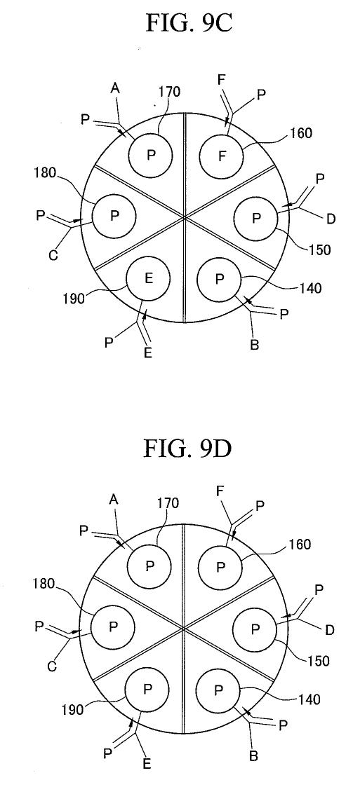

The multiple layers including three or more different layers may be also deposited using the ALD apparatus and the method of supplying gases according to another embodiment. Referring to FIG. 9A to FIG. 9D, a method of depositing multiple layers including three different types of layers will now be described below. The method can be implemented in an ALD apparatus including six separate reaction spaces through which substrates move in each of the three ALD depositions.

As described above, each reaction space may be selectively supplied with one reactant gas or an inert gas at any given time period during the process. For example, the reaction space 140 may be supplied with one of a second reactant gas B and an inert gas. The reaction space 150 may be supplied with one of a fourth reactant gas D and an inert gas. The reaction space 160 may be supplied with one of a sixth reactant gas F and an inert gas. The reaction space 170 may be supplied with one of a first reactant gas A and an inert gas. The reaction space 180 may be supplied with one of a third reactant gas C and an inert gas. The reaction space 190 may be supplied with one of a fifth reactant gas E and an inert gas.

As shown in FIG. 9A, during a time period, the reaction space 140 is supplied with the second reactant gas B. The reaction space 150 is supplied with an inert or purge gas P. The reaction space 160 is supplied with the inert gas P. The reaction space 170 is supplied with the first reactant gas A. The reaction space 180 is supplied with the inert or purge gas P. The reaction space 190 is supplied with inert or purge gas P. During this time period, the surface of each substrate sequentially transferred through the six reaction spaces 140 to 190 is exposed to the second reactant gas B, the inert gas P, the inert gas P, the first reactant gas A, the inert gas P, and the inert gas P in sequence such that a first thin film AB is deposited on the surface of each substrate by ALD. The gas supplying scheme shown in FIG. 9A can be used for the first time period t1 of FIG. 3B.

Referring to FIG. 9B, during another time period, the reaction space 140 is supplied with the inert gas P. The reaction space 150 is supplied with the fourth reactant gas D. The reaction space 160 is supplied with the inert gas P. The reaction space 170 is supplied with the inert gas P. The reaction space 180 is supplied with the third reactant gas C. The reaction space 190 is supplied with the inert gas P. During this time period, the surface of each substrate sequentially transferred through the six reaction spaces 140 to 190 is exposed to the inert gas P, the fourth reactant gas D, the inert gas P, the inert gas P, the third reactant gas C, and the inert or purge gas P such that a second thin film CD is deposited on the surface of each substrate by ALD. The gas supplying scheme shown in FIG. 9B can be used for the third time period t3 of FIG. 3B.

As shown in FIG. 9C, during yet another time period, the reaction space 160 is supplied with the sixth reactant gas F, while the reaction space 190 is supplied with the fifth reactant gas E. During this time period, the other reaction spaces 140, 150, 170, 180 are supplied with the inert gas P. The surface of each substrate sequentially transferred through the six reaction spaces 140 to 190 is exposed to the inert gas P, the inert gas P, the sixth reactant gas F, the inert gas P, the inert gas P, and the fifth reactant gas E in sequence such that a third thin film EF is deposited on the surface of each substrate by ALD. The gas supplying scheme shown in FIG. 9C can be used for the fifth time period t5 of FIG. 3B.

Referring to FIG. 9D, during yet another time period, all the reaction spaces 140-190 may be supplied with a purge gas. The gas supplying scheme shown in FIG. 9D can be used for the second, fourth, and sixth time periods t2, t4, t6 of FIG. 3B. The gas supply schemes shown in FIG. 9A to 9D may be combined to deposit multiple layers including three thin films AB, CD, and EF overlying one another in a desired order.

As described above, multiple layers including at least two layers of different materials may be deposited on a plurality of substrates in a relatively short period of time. In addition, the configurations of the ALD apparatuses of the embodiments reduce undesired deposition by reaction between reactant gases. In addition to purge curtains and whole reactant spaces separating reactant spaces that have reactant flowing, each reactant space is subject to only one reactant, despite use in deposition of multiple materials. This minimizes risk of interaction between mutually reactive reactants, except for on the substrate surfaces. Nevertheless, multiple types of deposition can be conducted in the same apparatus without unloading the substrates.

While this invention has been described in connection with what is presently considered to be certain exemplary embodiments, it is to be understood that the invention is not limited to the disclosed embodiments, but, on the contrary, is intended to cover various modifications and equivalent arrangements included within the spirit and scope of the appended claims.

I claim:

1. An atomic layer deposition (ALD) apparatus comprising:
a reaction chamber including a plurality of reaction spaces, the reaction chamber including a first set of inlets configured to introduce a first set of reactant gases for a first ALD process to the reaction spaces such that the first set of reactant gases are not mixed with one another, the reaction chamber also including a second set of inlets configured to introduce a second set of reactant gases for a second ALD process to the reaction spaces such that the second set of reactant gases are not mixed with one another;
a driver configured to move a plurality of substrates through the reaction spaces; and
a controller configured to supply the first set of reactant gases for a first period of time while moving the substrates through the reaction spaces for two or more complete cycles and to supply the second set of reactant gases for a second period of time while moving the substrates through the reaction spaces for two or more complete cycles.

2. The ALD apparatus of claim 1, wherein the reaction chamber comprises first, second, third and fourth reaction spaces, and wherein the controller is configured to supply a first reactant gas to the first reaction space, a second reactant gas to the third reaction space, and a purge gas to the second and fourth reaction spaces during the first period of time.

3. The ALD apparatus of claim 2, wherein the controller is further configured to supply during the second period of time: a third reactant gas to the second reaction space, a fourth reactant gas to the fourth reaction space, and a purge gas to the first and third reaction spaces.

4. The ALD apparatus of claim 3, wherein the controller is further configured to supply a purge gas to the first to fourth reaction spaces between the first and second periods of time and after the second period of time.

5. The ALD apparatus of claim 3, wherein
the reaction chamber further comprises fifth and sixth reaction spaces;
the controller is configured to supply a purge gas to the fifth and sixth reaction spaces during the first and second periods of time;
the controller is configured to supply for a third period of time: a fifth reactant gas to a fifth reaction space, a sixth reactant gas to the sixth reaction space, and a purge gas to the first, second, third and fourth fifth reaction spaces, and
the driver is configured to move the substrates through the first, second, fifth, third, fourth and sixth reaction spaces in sequence for two or more complete cycles during the third period of time.

6. The ALD apparatus of claim 5, wherein the controller is further configured to supply a purge gas to the first to sixth reaction spaces between the first and second periods of time and between the second and third periods of time.

7. The ALD apparatus of claim 1, further comprising a radio frequency (RF) source configured to activate at least one of the plurality of reactant gases in one of the reaction spaces.

8. An atomic layer deposition (ALD) apparatus configured for depositing multiple layers on multiple substrates, comprising:
a first reaction space in selective communication with a first ALD reactant;
a second reaction space in selective communication with a second ALD reactant;
a third reaction space in selective communication with a third ALD reactant;
a fourth reaction space in selective communication with a fourth ALD reactant;
a driver configured to move a plurality of substrates through the first, second, third and fourth reaction chambers; and
a controller connected to gas control systems and the driver, the controller configured to conduct a first ALD process on the substrates using the first and third ALD reactants and to conduct a second ALD process on the substrates using the second and fourth ALD reactants while the driver moves the substrates through the first, second, third and fourth reaction chambers.

9. The ALD apparatus of claim 8, wherein each of the reaction spaces is in communication with a source of purge gas, and the controller is configured to supply purge gas to the second and fourth reaction spaces during the first ALD process and to supply purge gas to the third and fifth reaction spaces during the second ALD process.

10. The ALD apparatus of claim 8, wherein the reaction spaces are positioned such that the driver can move the substrates through the first, second, third and fourth reaction spaces in order.

11. The ALD apparatus of claim 10, a further comprising a fourth reaction space in selective communication with a fifth ALD reactant and a sixth reaction space in selective communication with a sixth ALD reactant, wherein the fifth and sixth reactants are employed in conducting a third ALD process, and wherein the reaction spaces are positioned such that the first and third reaction spaces are not directly adjacent one another, the second and fourth reaction spaces are not directly adjacent one another, and the fifth and sixth reaction spaces are not directly adjacent one another.

12. A method of forming thin films on a plurality of substrates, the method comprising:
providing a plurality of reaction spaces including a first set of reaction spaces and a second set of reaction spaces;
loading a plurality of substrates into the reaction spaces such that each of the reaction spaces is loaded with at least one of the substrates;
supplying a first set of reactant vapors for a first ALD process into the first set of reaction spaces during a first period of time, wherein each of the first set of reactant vapors is supplied to a separate one of the first set of reaction spaces;
moving the substrates through the first set of reaction spaces for two or more complete cycles during the first period of time to thereby deposit a first film on the substrates;
supplying a second set of reactant vapors for a second ALD process into the second set of reaction spaces during a second period of time, wherein each of the second set of reactant vapors is supplied to a separate one of the second set of reaction spaces; and
moving the substrates through the second set of reaction spaces for two or more complete cycles during the second period of time to thereby deposit a second film on the substrates.

13. The method of claim 12, wherein
supplying the first set of reactant vapors during the first period of time comprises supplying a plurality of ALD reactants each to separate, non-adjacent reaction spaces of the first set of reaction spaces, and
supplying the second set of reactant vapors during the second period of time comprises supplying a plurality of ALD reactants each to separate, non-adjacent reaction spaces of the second set of reaction spaces.

14. The method of claim 13, further comprising, during each of the first and second periods of time, supplying purge gas to reactions spaces between the reaction spaces being supplied with reactant vapors.

15. The method of claim 14, wherein moving the substrates during the first and second periods of time comprises rotating a platform adjacent the reaction spaces, wherein the platform supports the substrates, such that the substrates are moved through both of the first and second sets of reaction spaces during each of the first and second periods of time.

16. The method of claim 12, wherein the plurality of reaction spaces further comprises a third set of reaction spaces, the method further comprising
supplying a third set of reactant vapors for a third ALD process into a third set of the reaction spaces during a third period of time, wherein each of the third set of reactant vapors is supplied to a separate one of the third set of reaction spaces; and
moving the substrates through the third set of reaction spaces for two or more complete cycles during the third period of time to thereby deposit a third film on the substrates.

17. The method of claim 16, wherein
supplying the first set of reactant vapors during the first period of time comprises supplying a plurality of ALD reactants each to separate, non-adjacent reaction spaces of the first set of reaction spaces,
supplying the second set of reactant vapors during the second period of time comprises supplying a plurality of ALD reactants each to separate, non-adjacent reaction spaces of the second set of reaction spaces; and
supplying the third set of reactant vapors during the third period of time comprises supplying a plurality of ALD reactants each to separate, non-adjacent reaction spaces of the third set of reaction spaces.

18. The method of claim 17, further comprising, during each of the first, second and third periods of time, supplying purge gas to reactions spaces between the reaction spaces being supplied with reactant vapors, and moving the substrates during each of the first, second and third periods comprises moving the substrates through each of the first, second and third sets of reaction spaces.

19. The method of claim 12, further comprising activating at least one of the reactant gas with radio frequency (RF) power.

20. The method of claim 12, further comprising supplying a purge gas to the first and second sets of reaction spaces between the first and second periods of time and after the second period of time.

21. The method of claim 12, wherein each of the first set of reaction spaces is interposed between two of the second set of reaction spaces.

22. A method of depositing a plurality of thin films on a substrate, the method comprising:
conducting a first atomic layer deposition (ALD) of a first thin film on the substrate during a first period of time, the first ALD comprising:
supplying at least first and second ALD reactants into first and third reaction spaces, respectively,
supplying purge gas into second and fourth reaction spaces, and
moving the substrate through the first, second, third and fourth reaction spaces in at least two cycles; and
subsequently conducting a second atomic layer deposition (ALD) of a second thin film on the substrate during a second period of time, the second ALD comprising:
supplying at least third and fourth ALD reactants into the second and fourth reaction spaces, respectively,
supplying purge gas into the first and second reaction spaces, and
moving the substrate through the first, second, third and fourth reaction spaces in at least two cycles.

23. The method of claim 22, further comprising, conducting a third ALD process to form a third thin film on the substrate during a third period, the third ALD process comprising:
supplying at least fifth and sixth ALD reactants into fifth and sixth reaction spaces, respectively,
supplying purge gas into the first, second, third and fourth reaction spaces, and
moving the substrate through the first, second, fifth, third, fourth and sixth reaction spaces in at least two cycles

24. The method of claim 22, wherein moving the substrate through the first, second, third and fourth reaction spaces comprises rotating the substrate upon a platform beneath the first, second third and fourth reaction spaces arranged in order along a closed circuit substrate movement path.

25. The method of claim 22, wherein moving the substrate comprises rotating at least four substrates supported on the platform through the first, second, third and fourth reaction spaces.
